(19) United States
(12) Patent Application Publication
(10) Pub. No.: US 2002/0151164 A1
(43) Pub. Date: Oct. 17, 2002

(54) Structure and method for depositing solder bumps on a wafer

(76) Inventors: Hunt Hang Jiang, San Jose, CA (US); Mark McCormack, Livermore, CA (US); Lei Zhang, San Jose, CA (US)

Correspondence Address: COUDERT BROTHERS, 600 Beach Steet, San Francisco, CA, 94111, US

(21) Appl. No.: 09/834,273

(22) Filed: Apr. 12, 2001

(51) Int. Cl. H01L 21/44

(52) U.S. Cl. 438/613

(57) ABSTRACT

A method for depositing solder bumps on a circuit substrate. The method comprises forming a dielectric layer on the circuit substrate which includes a plurality of conductive regions. The dielectric layer is patterned and opened to expose the conductive regions. A solder bump is disposed on each of the conductive regions, and a barrier layer is disposed on each of the solder bumps. Subsequently, the method includes forming a second solder bump on each of the first solder bumps. In an alternative method, solder bumps are initially disposed on each of the conductive regions and are then covered with a dielectric material. Subsequently, the dielectric material and a portion of the solder bumps are removed, and a barrier layer is disposed on each of the remaining structures of the solder bumps. The second solder bump material may then be disposed on the barrier layer. The articles produced by the methods of the present invention include semiconductor substrates or wafers having stacked solder bumps.

### BACKGROUND OF THE INVENTION

1. Field of the Invention

The present invention relates to depositing solder bumps on a substrate, such as a circuit substrate. More particularly, embodiments of the present invention provide semiconductor structures and methods for forming a stack of solder bumps on top of each other on a circuit substrate, such as a semiconductor wafer.

2. Description of the Prior Art

Semiconductor device packages or integrated circuit (IC) chips may, in general, operate by means of being mounted on a substrate, such as a semiconductor wafer or a printed circuit substrate, which comprises an interconnection pattern for a circuit to be assembled, to electrically connect with other electrical/electronic devices (e.g. resistors, capacitors, ICs). For the purpose of electrically connecting to other such devices over the interconnection pattern, the semiconductor device packages or the IC chips comprise a number of external electrodes, while the interconnection pattern on the substrate contains a number of contact pads to be connected to the external electrodes of the semiconductor device packages or of the IC chips. Various methods for electrically connecting semiconductor device packages or IC chips to semiconductor wafers or printed circuit substrates are well known in the art. An electrically-conductive bond (e.g., a solder bump) may be used to mechanically and electrically connect to semiconductor wafers or printed circuit substrate.

In recent years, leadless packages, also known as chip carriers, have come into increasing use for accommodating integrated circuits (IC), large-scale integrated circuits (LSI), and the like. Like conventional packages with outer leads, leadless packages accommodate an IC chip therein and outer pads of the leadless package are electrically connected to the substrate and circuit board by soldering. They therefore can be used in popular assembly processes. At the same time, provision of conductor pads as outer pads in place of outer leads enables a more compact structure. Therefore, such packages can be mounted at a higher density on a substrate, compared with other packages. This feature has resulted in leadless packages being widely used in a broad range of fields.

There is, however, a problem with mounting the package to the substrate and circuit board by a rigid soldering technique in that the electrical connections tend to fracture as a result of thermal cycling or other reasons. Normally, the package, the semiconductor substrate, and the circuit board are formed of different materials having different coefficients of expansion. During the heating required to accomplish the mounting and during normal operating conditions, the package, semiconductor substrate, and the circuit board contract and expand at different rates, thereby generating stresses. These stresses can fracture the package, the semiconductor substrate, the circuit board, or soldered conductor pads. The problem is compounded the greater the size of the devices on the circuit board. Such breakage, of course, has a fatal effect on the operation of the electronic circuits formed in the semiconductor wafer or on the circuit board. Therefore, what is needed and what has been invented inter alia is a method for forming solder bumps, especially for stacking solder bumps on top of each other on a circuit substrate in order to provide a greater stand-off height between chips and the circuit substrate to reduce the likelihood that the formed solder bump(s) will break over time.

### SUMMARY OF THE INVENTION

An embodiment of the present invention provides a method for forming solder bumps, more specifically two or more solder bumps formed in a stacked relationship. In one embodiment of the present invention, there is provided an article which may be produced in accordance with any of the methods of the present invention. In another embodiment of the invention a method for producing the article comprises forming a dielectric layer (e.g., a photoimageable dielectric layer) on a circuitized substrate (e.g., a semiconductor wafer) having a conductive region; opening the dielectric layer to expose the conductive region; and forming a first solder bump on the conductive region. The method further comprises forming a diffusion barrier on the first solder bump and forming a second solder bump on the first solder bump. The first and second solder bumps each preferably comprise a different solder composition. The first solder bump has a reflow temperature which is preferably greater than the reflow temperature of the second solder bump. The first solder bump may include a dome-shaped surface which partly protrudes above a top surface of the dielectric layer and which terminates below the top surface of the dielectric layer at a defined distance therefrom. The diffusion barrier preferably comprises a thickness having a value generally equal to the defined distance. The diffusion barrier has a top barrier surface and lies on the dome-shaped surface. An exterior surface of the second solder bump generally terminates at a juncture point of the top barrier surface of diffusion barrier and the top surface of the dielectric layer.

In another embodiment of the present invention there is provided a method for producing an article (e.g., a semiconductor article) comprising forming a circuitized substrate (e.g., a semiconductor wafer) having a conductive region (e.g., an electrical pad); disposing a first solder bump on the conductive region; and laminating a dielectric layer to the circuitized substrate and on the first solder bump. The method further includes abrading, cutting, or the like, the dielectric layer to expose a portion of the first solder bump; depositing a diffusion barrier on the exposed portion of the first solder bump; and forming a second solder bump on the diffusion barrier. Abrading, cutting, or the like, preferably additionally comprises abrading, cutting, or the like, the first solder bump to expose the inside of the first solder bump. The inside of the first solder bump comprises an internal planar surface, which is located below a top surface of the dielectric layer at a defined distance therefrom. The diffusion barrier is disposed on the internal planar surface, and includes a thickness having a value generally equal to the defined distance.

Further embodiments of the present invention provide for articles, more specifically semiconductor articles. In one embodiment there is provided an article comprising a substrate; a conductive layer disposed on the substrate; and a first solder bump having a generally dome-shaped surface and disposed on the conductive region. A dielectric layer with a top surface is located on the substrate and a diffusion barrier is positioned on the generally dome-shaped surface. A second solder bump is disposed on the diffusion barrier. The generally dome-shaped surface partly protrudes above the top surface of the dielectric layer and terminates below the top surface of the dielectric layer at a defined distance therefrom. The diffusion barrier comprises a thickness having a value generally equal to the defined distance. Preferably, the first solder bump has a higher reflow temperature than a reflow temperature of the second solder bump. The second solder bump covers the diffusion barrier and includes an exterior surface that generally terminates at a juncture point of the top barrier surface of diffusion barrier and top surface of the dielectric layer.

In another embodiment for the article, the article includes a substrate; a conductive layer disposed on the substrate; and a first solder bump having an abraded or severed internal planar surface and disposed on the conductive region. The article includes a dielectric layer having a top surface and positioned on the substrate and a diffusion barrier placed on the abraded or severed internal planar surface. The article further includes a second solder bump disposed on the diffusion barrier. The abraded or severed internal planar surface is disposed below the top surface of the dielectric layer at a defined distance therefrom. Preferably, the diffusion barrier comprises a thickness having a value generally equal to the defined distance, and the first solder bump has a higher reflow temperature than a reflow temperature of the second solder bump which includes an exterior surface that generally terminates at a juncture point of a top barrier surface of diffusion barrier and the top surface of the dielectric layer. The top barrier surface is generally aligned with the top surface of the dielectric layer.

These provisions together with the various ancillary provisions and features which will become apparent to those skilled in the art as the following description proceeds, are attained by the methods and articles of the present invention, preferred embodiments thereof being shown with reference to the accompanying drawings, by way of example only, wherein:

### BRIEF DESCRIPTION OF THE DRAWINGS

FIG. 1 is a side elevational view of a wafer structure having a plurality of conductive regions;

FIG. 2 is the side elevational view of the wafer structure of FIG. 1 with a solder bump disposed on each of the conductive regions;

FIG. 3 is the side elevational view of the wafer structure of FIG. 2 after a dielectric material has been disposed on the exposed portions of the wafer and over the solder bumps;

FIG. 4A is a side elevational view of the wafer structure of FIG. 3 after a portion of the dielectric layer and the solder bumps has been removed by grinding or the like in order to reduce the height of the dielectric material and the solder bumps;

FIG. 4B is an enlarged view of one of the solder bumps in FIG. 4A, disclosing a planar surface of the solder bump being lower than the surface of the dielectric material;

FIG. 5A is a side elevational view of the wafer structure of FIG. 4A after a barrier layer has been disposed on each of the planar surfaces of the solder bumps;

FIG. 5B is an enlarged side elevational view of one of the solder bumps in FIG. 5A, disclosing the barrier layer as having a thickness which is approximately equal to the distance that the planar surface of the solder bump is below the surface of the dielectric material;

FIG. 6 is the side elevational view of the wafer structure of FIG. 5A after a second solder bump has been disposed on each of the barrier layers;

FIG. 7 is a side elevational view of a wafer structure illustrating another embodiment for stacking solder bumps;

FIG. 8 is a side elevational view of a wafer substrate having a plurality of conductive regions;

FIG. 9 is a side elevational view of the wafer structure of FIG. 8 after a dielectric layer has been placed over the exposed portions of the wafer structure and over the conductive regions;

FIG. 10 is a side elevational view of the wafer structure of FIG. 9 after the wafer structure has been patterned and a portion of the dielectric material has been removed to expose the conductive regions;

FIG. 11 is a side elevational view of the wafer structure of FIG. 10 after a solder material has been disposed on the exposed conductive regions and partially over the dielectric layer;

FIG. 12A is a side elevational view of the wafer structure of FIG. 11 after the solder materials have been reflowed such that a generally dome-shaped structure is formed by each of the solder materials;

FIG. 12B is an enlarged side elevational view of one of the solder bumps of FIG. 12A disclosing the dome-shaped surface terminating below the top surface of the dielectric layer;

FIG. 12C is the enlarged view of FIG. 12B after a barrier layer has been disposed on the dome-shaped surface of the solder material in FIG. 12B such that an external dome-shaped surface of the barrier layer terminates at the juncture point of the external dome-shaped surface of the barrier layer and the top surface of the dielectric layer;

FIG. 13 is a side elevational view of the wafer structure of FIG. 12A after a barrier layer has been placed over the dome-shaped surface of each of the reflowed solder bumps;

FIG. 14 is a side elevational view of the wafer structure of FIG. 13 after a second solder material has been placed over the barrier layer and partially over and on the top surface of the dielectric layer; and

FIG. 15 is a side elevational view of the wafer structure of FIG. 14 after the second solder material has been reflowed such that the second solder material forms a spheroid and includes an exterior curvaceous surface that generally terminates at a juncture point of the external dome-shaped surface of the barrier layer and the top surface of the dielectric layer.

### DETAILED DESCRIPTION OF PREFERRED EMBODIMENTS OF THE INVENTION

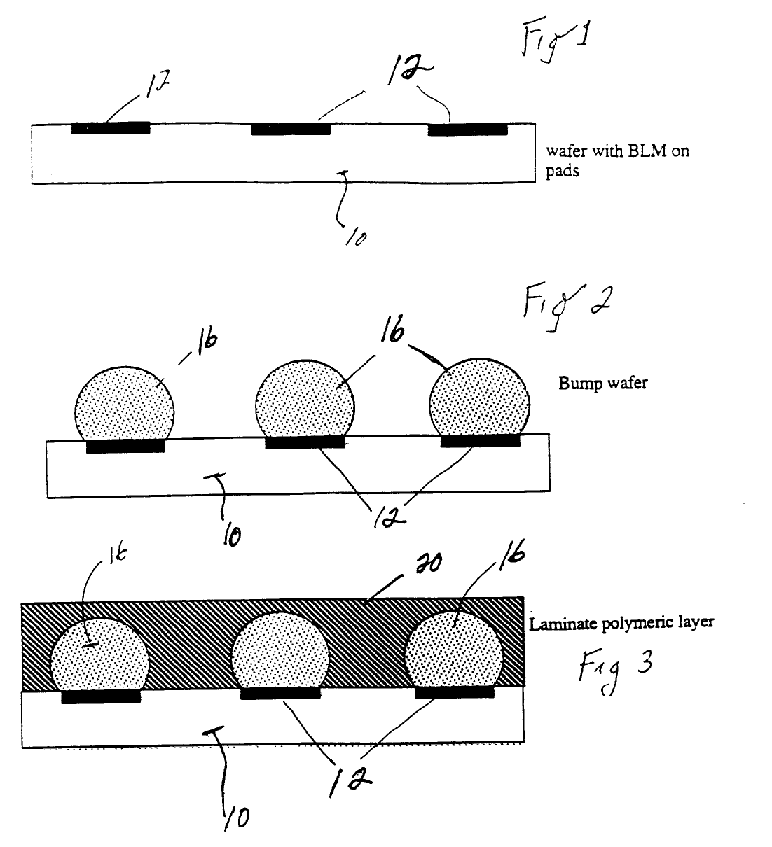

Referring in detail now to the drawings, there is seen in FIG. 1 a substrate 10 (e.g., a circuit board or a semiconductor wafer or the like) having connected or bonded thereto a plurality of conductive regions 12-12-12 (e.g., electrode pads, or the like), which may be composed of any suitable metal component, such as aluminum or copper. A solder bump 16 is placed on each of the conductive regions 12, as best shown in FIG. 2. Solder bump 16 may be composed of any suitable metal component, such as lead (Pb) and tin (Sn) or any suitable eutectic composition. Preferably, solder bumps 16 are lead-free with a melting temperature (e.g., 5° C. to 50° C.) above the reflow processing temperatures of solder bump (identified as “30” below) such as eutectic Pb/Sn (e.g., Sn/5Sb, Au/20 Sn, etc.) By solder bumps 16 being lead-free, there are provided solder bumps which may be used (e.g., such as with eutectic Pb/Sn stacked solder bumps) in flip chip and chip scale packaging assembly at sufficient standoff from devices (e.g., circuitized substrate 10) to negate any concerns of alpha particle emission from Pb isotopes. It has been discovered that tin (Sn) is the preferred material for solder bumps 16 for preventing or negating any concerns of alpha particle emission from Pb isotopes.

Solder bumps 16 may have any geometric shape, preferably a spheroid as seen in FIG. 2. The solder bumps 16 may be formed by any suitable method, such as by stencil printing (“stenciling flux”). By way of example only, vapor deposition may be employed to dispose a layer of the soldering material which forms the solder bumps 16. Subsequently, the soldering material is heated to its softening or melting temperature (“reflow temperature”), after which the solder bumps 16 become generally spherical in vertical cross section due to surface tension. Solder bumps 16 typically have an oxide layer on the surface as a result of air contact. The soldering material may be heated without flux, such as in atmospheric gas consisting of nitrogen and/or argon. The melting temperature of the solder bumps 16 is preferably lower than that of the conductive regions 12. After solder bumps 16 have been suitable disposed on the conductive regions 12 of the substrate 10, a dielectric layer 20 is disposed over solder bumps 16 and the exposed area of the dielectric layer 20.

Suitable dielectric material for dielectric layer 20 include B-stage polymeric compounds, such as polyimides, epoxy resins, polyurethanes or silicons, well known to those skilled in the art. Additional suitable material for dielectric layer 20 include any material(s) wherein vias may be formed by one or more of the following methods, by way of example only: photoimageable, laser ablation, plasma and/or chemical etching. For example, suitable materials could include, as illustrated in U.S. Pat. No. 5,579,573 incorporated herein by reference thereto, thermosetting materials, such as high glass transition anhydride-cured epoxy composition. More particular suitable thermoset materials include, but are not limited to, one or more compounds selected from group consisting of epoxies and modified epoxies, melamine-formaldehydes, urea formaldehydes, phelonic resins, poly(bis-maleimides), acetylene-terminated BPA resins, IPN polymers, triazine resins, and mixtures thereof. The thermoset material may be dispensed in an unpolymerized state onto the exposed surface of substrate 10 and over the solder bumps 16 as best shown in FIG. 3. As previously indicated, a subsequent heating step may be preferably necessary to partially react the material of the dielectric layer 20 into a “B-stageable” thermoplastic-like material, capable of reflowing and/or curing the material of the dielectric layer 20 into a ternary matrix upon additional exposure to heat and pressure. Additional suitable material for the dielectric layer 20 may include high temperature thermoplastic materials such as liquid crystal polyesters (e.g., Xydar™ or Vectra™), poly-(ether ether ketones), or the poly(aryl ether ketones). Further additional suitable thermoplastic materials include, by way of example only, ABS-containing resinous materials (ABS/PC, ABS/polysulfone, ABS/PVC), acetals acrylics, alkyds, allylic ethers, cellulosic esters, chlorinated polyalkylene ethers, cyanate, cyanamides, furans, polyalkylene ethers, polyamides (Nylons), polyarylene ethers, polybutadienes, polycarbonates, polyesters, polyfluorocarbons, polyimides, polyphenylenes, polyphenylene sulfides, polypropylenes, polystyrenes, polysulfones, polyurethanes, polyvinyl acetates, polyvinyl chlorides, polyvinyl chloride/vinylidine chlorides, polyetherimedes, polyether ether imides, and the like, and mixtures of any of the foregoing.

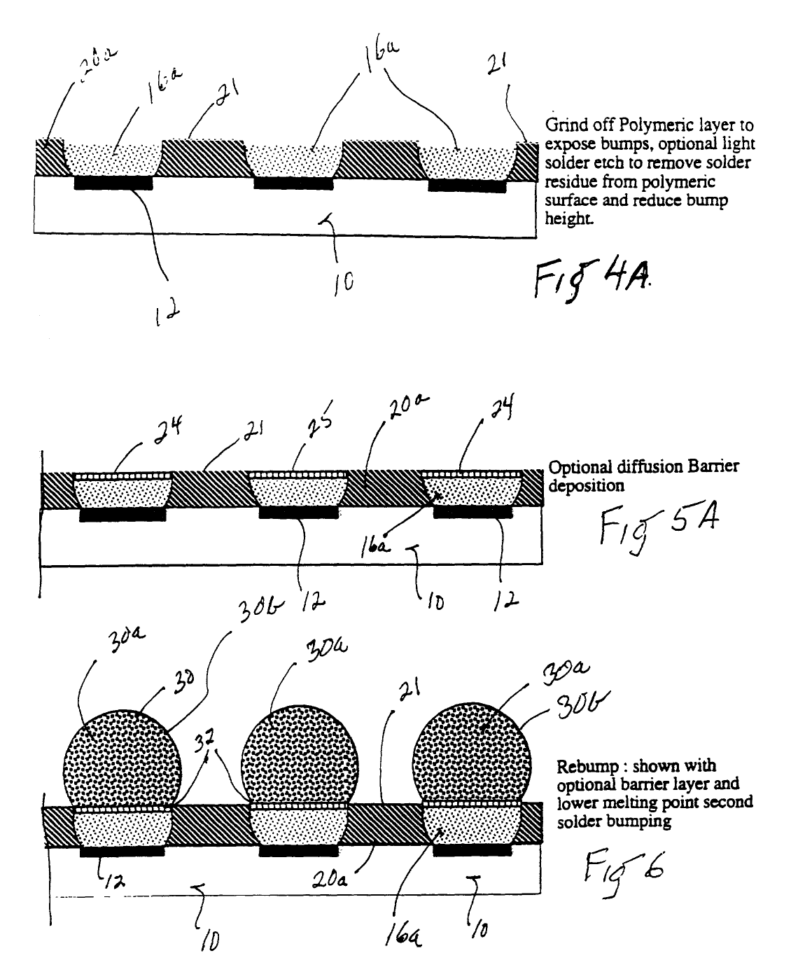

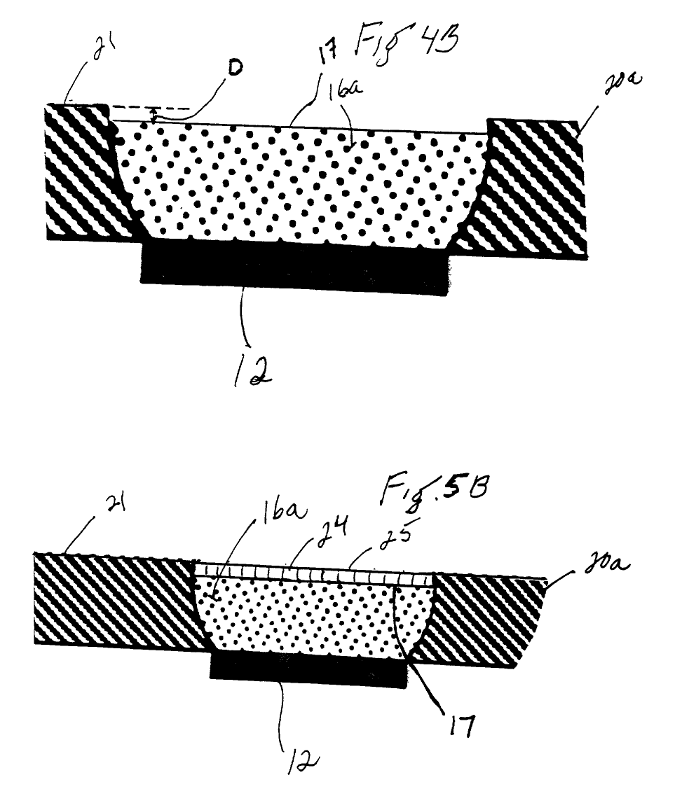

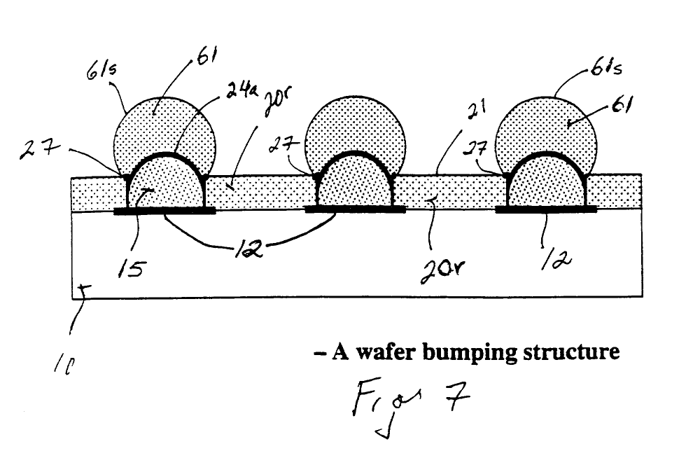

After the material for the dielectric layer 20 has been positioned on substrate 10 and over the solder bumps 16, portions of the dielectric layer 20, preferably portions of both the dielectric layer 20 and the solder bumps 16, are removed. Removing of portions of the dielectric layer 20, and preferably also the solder bumps 16, may be performed by any suitable manner to produce residual dielectric layer 20a and residual solder bumps 16a-16a-16a, such as by grinding, polishing, etching, severing, abrading, or by any of the like. Thus, by way of example only, the top portions of dielectric layer 20 and the solder bumps 16 may be grinded or abraded, followed optionally by etching with plasma or chemicals to remove solder residue off of the surface of the dielectric layer 20 and to further remove solder material from the respective solder bumps 16 to further reduce the height of each solder bump 16 to produce residual solder bumps 16a-16a-16a having a generally planar surface 17 that is below a dielectric surface 21 of the dielectric layer 20a by a distance of D (see FIG. 4B), which ranges from about 0.01% to about 50%, preferably from about 2% to about 25%, more preferably from about 5% to about 15% of the value of the thickness of residual dielectric layer 20a. Subsequently, as best shown in FIGS. 5A and 5B, a barrier layer 24 may be disposed on the planar surface 17 of each of the solder bumps 16a. The disposing of the barrier layer 24 may be accomplished by any suitable manner, preferably by electroless immersion or electrolytic plating. The barrier layer 24 may be composed of any material that is capable of preventing diffusion of any of the matter contained in solder bumps 16a into solder bumps (identified as “30” below) superimposed over or on solder bumps 16a, and vice versa.

Barrier layer 24 preferably comprises a metal from Group VIIIB of the periodic table by Mendeleef. More preferably, the barrier layer 24 comprises nickel (Ni) such as electroless nickel. The barrier layer 24 also preferably comprises a coating or outside layer of a noble metal, more preferably an immersion coating of a noble metal, such as gold, having a coating thickness ranging from about 0.01 μm to about 2 μm. The barrier layer 24 preferably has a thickness approximately the value of D, the distance of dielectric surface 21 from planar surface 17 of one of the solder bumps 16a. Preferably, the thickness of the barrier layer 24 ranges from about 0.05 μm to about 20 μm, preferably from about 1 μm to about 15 μm, more preferably from about 2 μm to about 10μm. Barrier layer 24 includes a planar surface 25 which is preferably generally aligned with the dielectric surface 21 of the residual dielectric layer 20a.

Subsequent to the positioning or plating of the barrier layer 24 onto planar surface 17 of solder bump 16a, solder bumps 30-30-30 are respectively disposed onto planar surface 25 of the barrier layer 24. Solder bump 30 may be disposed by any suitable manner, such as by stencil printing or by reflowing of material 30a after suitably depositing material 30a on the planar surface 25 of the barrier layer 24. Material 30a may be any suitable material having a reflow processing temperature lower than the melting temperature of residual solder bump 16a. Preferably, material 30a comprises an eutectic Pb/Sn paste (e.g., Sn/5Sb, Au/20Sn, etc.). After solder bumps 30 have been suitably formed and disposed, they will respectively have an outer curvaceous surface 30b that generally terminates at juncture point 32 (see FIG. 6), the juncture point of the planar surface 25 of the barrier layer 24 with dielectric surface 21 of the residual dielectric layer 20a.

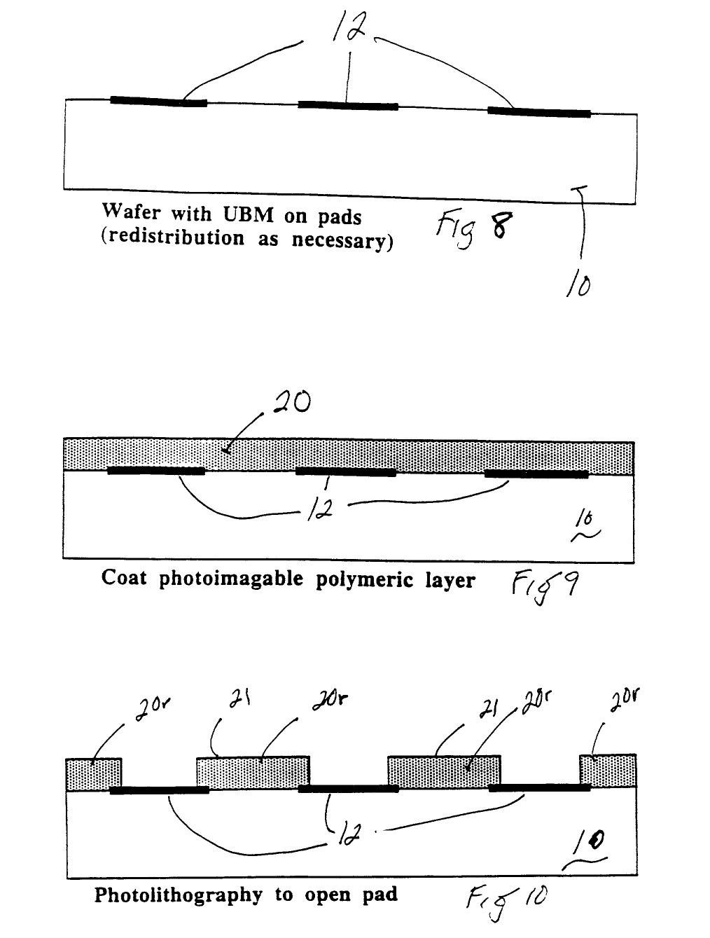

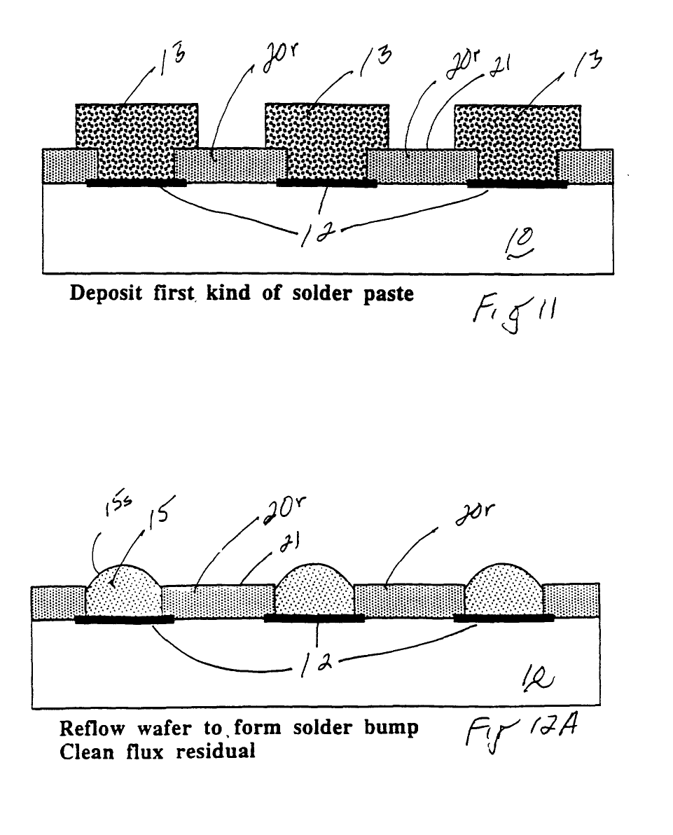

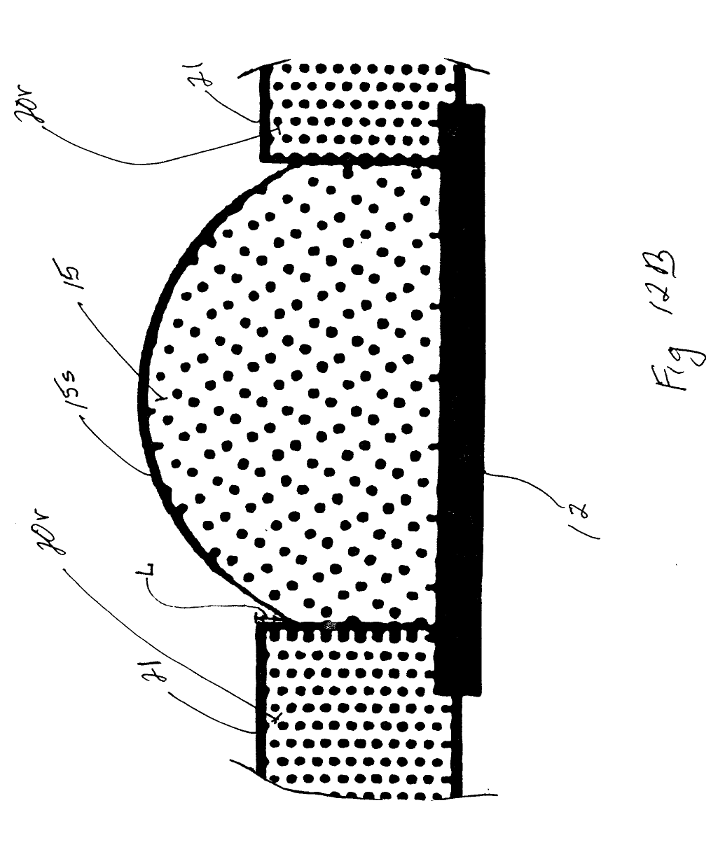

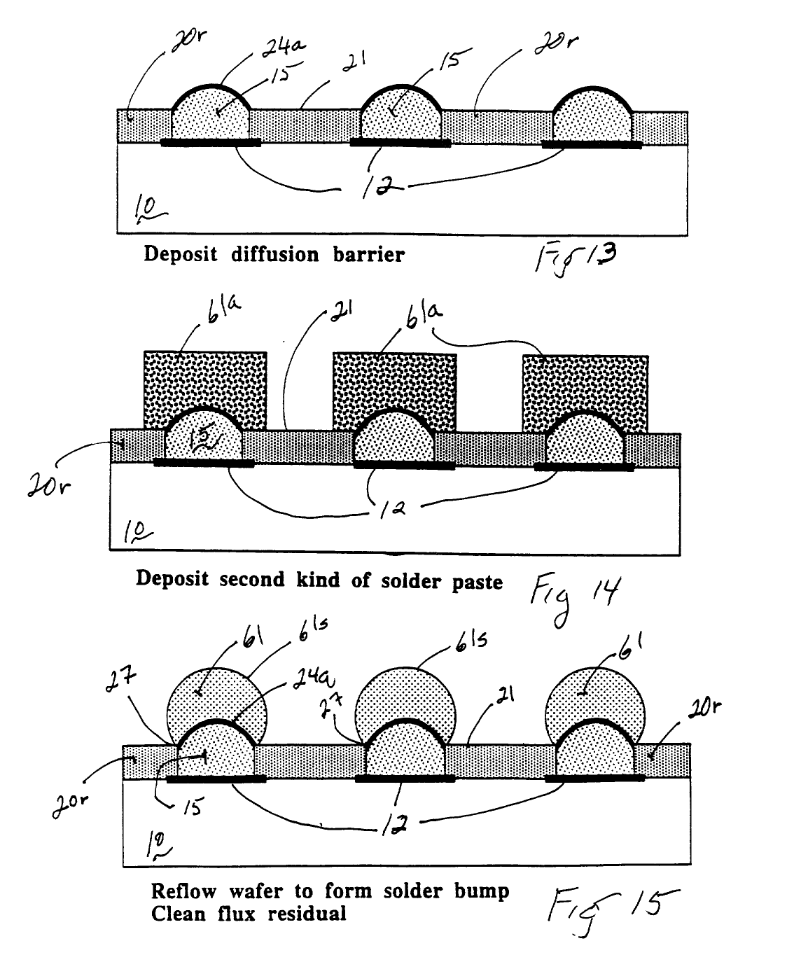

Referring now to FIGS. 7-15 for another embodiment of the present invention, there is seen substrate 10 supporting the conductive regions 12. As best shown in FIG. 9, the dielectric layer 20 is then disposed over the exposed areas of the conductive regions 12 and of the substrate 10. Subsequently, dielectric layer 20 is patterned and etched to expose conductive regions 12. Stated alternatively, dielectric layer 20 is photolithographically processed to open conductive regions 12, leaving spaced residual dielectric layers 20r.

After dielectric layer 20 has been photolithograpically processed, solder paste 13 is disposed on each conductive region 12 to fill the space between contiguous spaced residual dielectric layers 20r and lie partly on dielectric surface 21 of each of the residual dielectric layers 20r. Solder paste 13 is preferably the same composition and possesses the same temperature characteristics as solder bumps 16 and/or residual solder bumps 16a (e.g., tin).

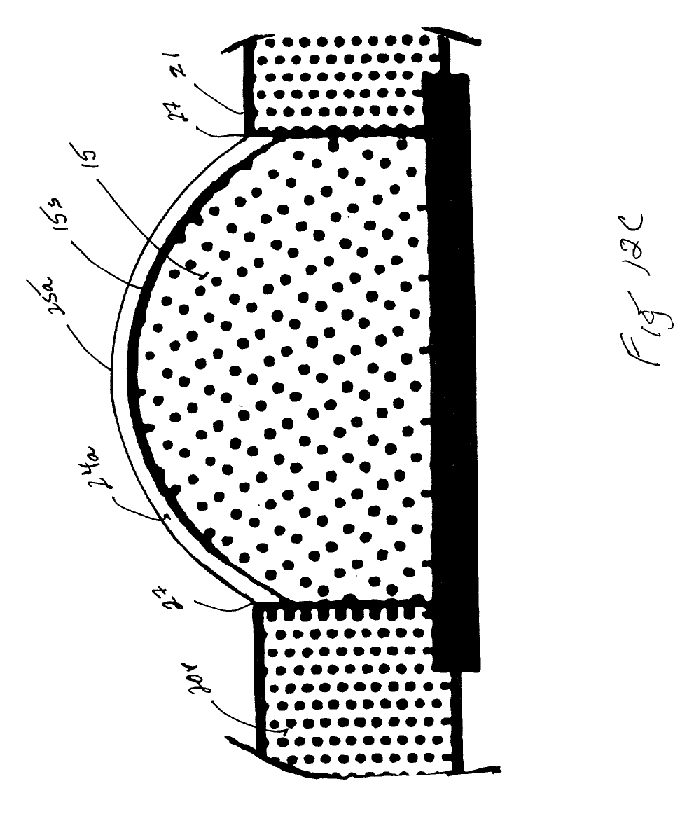

After solder paste 13 has been suitably disposed, it is reflowed to form solder bumps 15, each having a dome-shaped exterior surface 15s as best shown in FIGS. 12A and 12B. Residual flux including any solder paste 13 on the dielectric surface 21 may be cleaned by any well-known means, such as by etching, etc. The dome-shaped surface 15s of the solder bumps 15 partly protrudes above the dielectric surface 21 and terminates below the dielectric surface 21 at a defined distance L therefrom, as best shown in FIG. 12B. Distance L has a value approximating the value of D (see FIG. 4B) for the embodiment of the invention in FIGS. 1-10. Therefore, L has a value ranging from about 0.01% to about 50%, preferably from about 2% to about 25%, more preferably from about 5% to about 15% of the value of the thickness of residual dielectric layer 20r.

Barrier layer 24a may be disposed on surface 15s of solder bump 15 in the same manner that it may be disposed on surface 17 of residual solder bump 16a. Barrier layer 24a for the embodiment of the invention in FIGS. 7-15 may be composed of any material that is capable of preventing diffusion of any of the matter, material, or substance contained in solder bumps 15 into solder bumps (identified as “61” below) superimposed on or over surface 15s of solder bumps 15, and vice versa. Barrier layer 24a for this embodiment of the invention preferably comprises the same material(s) (e.g., Ni with Au immersion coating) and in the same quantities as barrier layer 24 for the embodiment of the invention in FIGS. 1-6. Barrier layer 24a in FIGS. 7-15 is arcuate and has a thickness approximating the value of L, the distance from dielectric surface 21 to a lower point on the residual dielectric layer 20r. Preferably, the thickness of the barrier layer 24a ranges from about 0.05 μm to about 20 μm, preferably from about 1 μm to about 15 μm, most preferably from about 2 μm to about 10 μm. Barrier layer 24a includes arcuate surface 25a which preferably terminates at juncture point 27 (see FIG. 12c), the termination point of dielectric surface 21.

After depositing or plating of barrier layer 24a on arcuate surface 15s of each of the solder bumps 15, solder bumps 61-61-61 are respectively formed on the arcuate surface 25a of the barrier layer 24a. Solder bump 61 may be disposed on arcuate surface 25a by any suitable manner, such as by stencil printing or by reflowing material 61a after suitably depositing material 61a on the arcuate barrier surface 25a and partly on the dielectric surfaces 21 of residual dielectric layers 20r. Material 61a may be any suitable material, preferably one having a reflow processing temperature lower than the melting temperature of solder bumps 15. Preferably, material 61 a comprises an eutectic Pb/Sn paste (e.g., Sn/5 Sb, Au/20 Sn, etc.). Subsequent to solder bumps 61 having been suitably disposed, each solder bump 61 has an outer curvaceous surface 61s that terminates at juncture point 27 (see FIGS. 7 and 15), the juncture point of arcuate barrier surface 25a of barrier layer 24a with dielectric surface 21 of the residual dielectric layers 20r.

Thus, the practice of embodiments of the present invention, there is provided a method and structure to prepare semiconductor wafers for flip chip and chip scale packaging including wafer bumping and surface passivation. Such structure enables the use of eutectic Pb/Sn solder bumps in flip chip and chip scale packaging assembly at sufficient standoff from devices to negate any concerns of alpha particle emission from Pb isotopes. Also, the structure provides compliance in a high aspect ratio interconnection that increases reliability. The conductive pads of a semiconductor wafer are processed to make them suitable for solder bumping by a Pb-free solder with a melting point above the reflow processing temperatures of eutectic Pb/Sn (e.g., Sn/5Sb, Au-20Sn, etc.), including a solderable top surface layer and an optional barrier metal layer. A photoimageable polymeric layer is coated on wafer. The thickness of the polymeric coating is sufficient to negate any concerns of alpha particle emission from Pb isotopes. The more preferred thickness of the polymeric coating ranges from about 75μm to about 100 μm. Conductive pads are opened by photolithograph methods known in the art. Pb-free solder pastes, with a melting point above the reflow processing temperatures of eutectic Pb/Sn (such as Sn/5Sb, Au/20Sn, etc.), are deposited on the wafer structure by stencil printing. The first solder material is reflowed to form the first solder bumps, and then clean away any flux residual. A diffusion barrier (such as electroless Ni with an immersion Au coating) may then be plated upon the exposed solder areas. Eutectic Pb/Sn solder pastes are preferably deposited on top of first solder bump by stencil printing. The second solder material is reflowed to form the second solder bump, and then any flux residual may be removed for cleaning purposes. The thick film remaining on the wafer structure may serve one or more of the following multiple functions: alpha particle protection to circuits in the wafer structure; surface protection of the wafer structure from mechanical damage; and increased solder ball stand-off height for improved reliability. With respect to alpha particle protection to circuits in the wafer structure, lead (Pb) containing solders generate alpha particles from impurities in the solder. When an alpha particle hits a memory cell in a semiconductor circuit, it causes the cell to flip states, resulting in a memory error. It is believed that from about 75 μm to about 100 μm of an organic material is known to absorb alpha particle energy and may be added to the surface of memory devices. When the film is at least 75 μm thick, alpha particle protection is provided without using expensive low alpha particle Pb/Sn solder or introducing other processing steps.

With respect to surface protection of the wafer structure from mechanical damage, the film is preferably an organic layer that is not brittle, unlike the surface of a semiconductor device. It will protect the fragile surface of the semiconductor device from handling induced damage, such as scratches or particles. With respect to increased solder ball stand-off height for improved reliability, devices using solder connections to join a semiconductor to a package are known to fail from fatigue cracking of the solder connection. The fatigue occurs from temperature cycling of the device, and the unequal co-efficient of thermal expansion of the die and the substrate. The distance between the die and the substrate is the stand-off height, and increasing the stand-off height is known to improve fatigue life. The normal means to increase stand-off height is to increase the solder ball diameter, but this also increases the pitch and lowers the interconnection density. The bottom film layer constrains the solder, allowing a larger stand-off height, without increasing the pitch.

Embodiments of the present invention may be applied to flip chip package where the polymeric layer is preferably 75-125 μm thick. The aperture opening formed by lithography process is half the ball pitch used in the filp chip (e.g., 150, 180, 200, or 250 μm). The wafer pad diameter is about 30 μm larger than the aperture opening. The solder composition in the first applied solder is preferably 95Sn/5Sb or 80Au/20Sn. Eutectic Ph/Sn solder balls are bumped prior to sawing the wafer into individual units. The embodiments of the present invention may also be applied to CSP (chip scale package) where the polymeric layer is preferably 100-200 μm thick. The aperture opening formed by lithography process is half the ball pitch used in the CSP (e.g., 500, 650, 750, or 800 μm). The wafer pad diameter is preferably 50 μm larger than the aperture opening. The solder composition in the first applied solder is 95Sn/5Sb or 80Au/20Sn. Eutectic Pb/Sn solder balls are preferably bumped prior to sawing the wafer into individual units.

Additional embodiments of the present invention provide for a method and structure to prepare semiconductor wafers for flip chip assembly including wafer bumping and surface passivation. The structure provides compliance in a high aspect ratio interconnection that increases reliability. The structure enables the use of eutectic Pb/Sn solder bumps in flip chip assembly at sufficient standoff from devices to negate any concerns of alpha particle emission from Pb isotopes. The pads of a semiconductor wafer are processed to make them suitable for solder bumping by a Pb-free solder with a melting point above the reflow processing temperatures of eutectic Pb/Sn (e.g., Sn-5Sb, Au/20Sn, etc.), including a solderable top surface layer and an optional barrier metal layer. Conductive pads are bumped with Pb-free solder by methods known in the art. As previously indicated, a polymeric layer is deposited over such as to cover the bumps. The deposition temperatures (and curing temperatures if thermosetting) of the polymeric layer is preferably below the melting point of the Pb-free solder. This polymeric layer may be deposited as a film, liquid or fluidized power bed. It may also be pressed or autoclaved on (as with molding sheet of compound.

The polymeric layer may then ground down to expose the embedded solder bumps. In order to be effective as an alpha particle barrier the polymeric layer preferably retains a thickness of at least ˜75 μm. An optional light solder etch may be performed to remove solder residue from polymeric surface and reduce embedded bump height. These exposed solder areas may now serve as pads for subsequent bumping. An optional diffusion barrier (such as electroless Ni with an immersion Au coating) may then be plated upon the exposed solder areas. Solder paste of lower melting point is then reflowed upon the exposed pads. Alternatively, solder balls may be attached and then reflown. The wafer is then diced such that each die is a bumped flip chip device.

The portion of the film remaining on the wafer may serve one or more multiple functions. The film may serve as a surface protector of the wafer from mechanical damage. The bottom layer of the film is preferably an organic layer that is not brittle, unlike the surface of a semiconductor device. It will protect the fragile surface of the semiconductor device from handling induced damage, such as scratches or particles. The film may serve to provide increased solder ball stand-off height for improved reliability. Devices using solder connections to join a semiconductor to a package are known to fail from fatigue cracking of the solder connection. The fatigue occurs from temperature cycling of the device, and the unequal co-efficient of thermal expansion of the die and the substrate. Because the distance between the die and the substrate is the stand-off height, increasing the stand-off height improves fatigue life. The normal means to increase stand-off height is to increase the solder ball diameter, but this also increases the pitch and lowers the interconnection density. The bottom film layer constrains the solder, allowing a larger stand-off height, without increasing the pitch. The film may also serve as an alpha particle protection to circuits in the wafer. Lead (Pb) containing solders generate alpha particles from impurities in the solder. As previously indicated, when an alpha particle hits a memory cell in a semiconductor circuit it causes the cell to flip states, resulting in a memory error. The organic material of this film of this invention having a 75-100 μm thickness, absorbs an alpha particle energy and may be added to the surface of memory devices. When the bottom layer of the film is at least about 75 μm thick, alpha particle protection is provided without extra processing steps.

Therefore, embodiments of the invention relate to preparing semiconductor chips for mounting, especially by flip chip bonding methods. One goal of the invention is to provide a greater stand-off height between the chips and a circuit substrate. Increasing the stand-off height between a chip and a substrate can reduce the likelihood that a conductive joint between the chip and substrate will break over time. By the practice of the present invention, it may be seen that the greater stand-off height can be provided by forming successive solder bumps on top of each other on a circuit substrate. The circuit substrate is preferably a semiconductor substrate which is to be diced into individual chips. Solder bumps can be stacked on a semiconductor substrate to provide an elongated solder body. A diffusion barrier may be present between the stacked solder bumps. In preferred embodiments, solder bumps may be formed of different solder compositions. The solder bumps closer to the semiconductor substrate have a higher reflow temperature than the solder bumps farther away from the semiconductor substrate.

While the present invention has been described herein with reference to particular embodiments thereof, a latitude of modification, various changes and substitutions are intended in the foregoing disclosure, and it will be appreciated that in some instances some features of the innovation will be employed without a corresponding use of other features without departing from the scope and spirit of the invention as set forth. Therefore, many modifications may be made to adapt a particular situation or material to the teachings of the invention without departing from the essential scope and spirit of the present invention. It is intended that the invention not be limited to the particular embodiment disclosed as the best mode contemplated for carrying out this invention, but that the invention will include all embodiments and equivalents falling within the scope of the appended claims.

What is claimed is:

1. A method comprising:
forming a dielectric layer on a circuitized substrate having a conductive region;
opening the dielectric layer to expose the conductive region;
forming a first solder bump on the conductive region;
forming a diffusion barrier on the first solder bump; and
forming a second solder bump on the first solder bump.

2. The method of claim 1 wherein the first and second solder bumps each comprise a different solder composition.

3. The method of claim 1 wherein a reflow temperature of the first solder bump is greater than a reflow temperature of the second solder bump.

4. The method of claim 1 wherein the dielectric layer is a photoimageable dielectric layer.

5. The method of claim 1 wherein the circuitized substrate is a semiconductor wafer.

6. The method of claim 1 wherein said first solder bump includes a generally dome-shaped surface terminating below a top surface of the dielectric layer.

7. The method of claim 6 wherein said dome-shaped surface partly protrudes above said top surface of the dielectric layer and terminates below the top surface at a defined distance therefrom.

8. The method of claim 7 wherein said diffusion barrier comprises a thickness having a value generally equal to said defined distance.

9. The method of claim 8 wherein said diffusion barrier has a top barrier surface and is formed on said dome-shaped surface.

10. The method of claim 9 wherein said second solder bump covers said diffusion barrier and includes an exterior surface that generally terminates at a juncture point of said top barrier surface of diffusion barrier and said top surface of the dielectric layer.

11. The method of claim 1 wherein said first solder bump comprises tin and said second solder bump comprises lead and said diffusion barrier comprises a Group VIII B metal.

12. The method of claims 11 wherein said barrier additionally comprises a coating of a noble metal.

13. An article produced in accordance with the method of claim 1.

14. An article produced in accordance with the method of claim 12.

15. An article comprising a substrate; a conductive layer disposed on said substrate; a first solder bump including a generally dome-shaped surface and disposed on said conductive region; a dielectric layer having a top surface and disposed on said substrate; a diffusion barrier disposed on said generally dome-shaped surface; and a second solder bump disposed on said diffusion barrier.

16. The article of claim 15 wherein said generally dome-shaped surface partly protrudes above said top surface of said dielectric layer terminates below said top surface of said dielectric layer at a defined distance therefrom.

17. The article of claim 16 wherein said diffusion barrier comprises a thickness having a value generally equal to said defined distance, and said first solder bump has a higher reflow temperature then a reflow temperature of the second solder bump.

18. The article of claim 17 wherein said diffusion barrier has a top barrier surface and is formed on said dome-shaped surface, and said second solder bump covers said diffusion barrier and includes an exterior surface that generally terminates at a juncture point of said top barrier surface of diffusion barrier and said top surface of the dielectric layer.

19. The article of claims 15 wherein said first solder bump comprises tin and said second solder bump comprises lead and said barrier comprises a Group VIII B metal having a noble metal coating.

20. A method comprising:
forming a circuitized substrate having a conductive region;
disposing a first solder bump on the conductive region;
laminating a dielectric layer to the circuitized substrate and on the first solder bump;
abrading the dielectric layer to expose a portion of the first solder bump;
depositing a diffusion barrier on the exposed portion of the first solder bump; and forming a second solder bump on the diffusion barrier.

21. The method of claim 20 wherein the circuitized substrate is a semiconductor wafer.

22. The method of claim 20 wherein said abrading additionally comprises abrading the first solder bump to expose the inside of said first solder bump.

23. The method of claim 22 wherein said inside of said first solder bump comprises an internal planar surface.

24. The method of claim 23 wherein said internal planar surface is disposed below a top surface of said dielectric layer at a defined distance therefrom.

25. The method of claim 24 wherein said diffusion barrier is disposed on said internal planar surface.

26. The method of claim 25 wherein said diffusion barrier comprises a thickness having a value generally equal to said defined distance.

27. The method of claim 20 wherein said first solder bump comprises tin and said second solder bump comprises lead and said barrier comprises a Group VIII B metal having a noble metal coating.

28. An article produced in accordance with the method of claim 20.

29. An article comprising a substrate; a conductive layer disposed on said substrate; a first solder bump having an abraded internal planar surface and disposed on said conductive region; a dielectric layer having a top surface and disposed on said substrate; a diffusion barrier disposed on said abraded internal planar surface; and a second solder bump disposed on said diffusion barrier.

30. The article of claim 29 wherein said abraded internal planar surface is disposed below said top surface of said dielectric layer at a defined distance therefrom.

31. The article of claim 30 wherein said diffusion barrier comprises a thickness having a value generally equal to said defined distance, and said first solder bump has a higher reflow temperature than a reflow temperature of the second solder bump.

32. The article of claim 31 wherein said second solder bump covers said diffusion barrier and includes an exterior surface that generally terminates at a juncture point of a top barrier surface of diffusion barrier and said top surface of the dielectric layer.

33. The article of claim 32 wherein said top barrier surface is generally aligned with said top surface of the dielectric layer.

34. The article of claim 29 wherein said first solder bump comprises tin and said second solder bump comprises lead and said barrier comprises a Group VIII B metal having a noble metal coating.

35. The method of claim 7 wherein said defined distance ranges from about 0.01% to about 50% of the value of the thickness of the dielectric layer.

36. The method of claim 24 wherein said defined distance ranges from about 0.01% to about 50% of the value of the thickness of the dielectric layer.
